(19) United States
(12) Patent Application Publication
(10) Pub. No.: US 2020/0176276 A1
(43) Pub. Date: Jun. 4, 2020

(54) STRIPPER MACHINE FOR LIFT-OFF PROCESS AND METHOD FOR PROCESSING THEREOF

(71) Applicant: Shenzhen China Star Optoelectronics Semiconductor Display Technology Co., Ltd., Shenzhen, Guangdong (CN)

(72) Inventors: Tian OU, Shenzhen, Guangdong (CN); Changsi SU, Shenzhen, Guangdong (CN)

(21) Appl. No.: 15/743,956

(22) PCT Filed: Jan. 10, 2018
(86) PCT No.: PCT/CN2018/072139

§ 371 Date: Jan. 11, 2018

(30) Foreign Application Priority Data
Dec. 6, 2017 (CN) 201711279770.4

(51) Int. Cl. H01L 21/67; B01D 36/02; G03F 7/42; B04B 7/08

(52) U.S. Cl. CPC H01L 21/67023; H01L 21/67173; B04B 7/08; G03F 7/42; B01D 36/02

(57) ABSTRACT

The present invention relates to a stripper machine used in a lift-off process and a method for processing thereof. The stripper machine includes: a plurality of chambers arranged sequentially in multiple levels, a plurality of tanks connected to the plurality of chambers, a plurality of filters connected to the plurality of tanks, each the filters are connected to a next level chamber, a centrifugal filtration device is provided in each of the tank. The present application further includes a corresponding method thereof. The stripper machine used in the lift-off process and the method for processing thereof are provided in the present invention are designed to improve the stripping machine used in the lift-off process and the method for processing thereof, to solve the clogging problem of the filter in the traditional stripper machine in the lift-off process.

### RELATED APPLICATIONS

The present application is a National Phase of International Application Number PCT/CN2018/072139, filed on Jan. 10, 2018, and claims the priority of China Application 201711279770.4, filed on Dec. 6, 2017.

### FIELD OF THE DISCLOSURE

The disclosure relates to a semiconductor process technology field, and more particularly to a stripper machine for lift-off process and method for processing thereof.

### BACKGROUND

In the field of semiconductor processes, the photolithography process has been one of the indispensable steps in the fabrication process. As known in the art, the photolithography process includes the following steps: applying a photoresist on the substrate, using mask to expose the photoresist on the substrate to define a circuit pattern corresponding to the electronic product, so that the substrate under photoresist can be subjected to a subsequent etching process, to form a desired circuit pattern. Of course, to complete an electron product, it is necessary to repeat the above steps several times. Taking a TFT LCD array substrate as an example, it is necessary to perform photolithography through a plurality of masks to form a stacked structure. In the currently used TFT LCD array design, there are five masks need to be performed the photolithography to respectively complete forming five different layers of circuit patterns including a gate electrode layer (GE), a semiconductor layer (SE), a source drain layer (SD), contact holes (CH), and a pixel electrode layer (PE).

The lift-off process is usually used for mask reduction in the Thin Film Transistor, TFT processes, the lift-off process is first forming a photoresist and patterned, then forming a film on the photoresist, at the time to removing the photoresist, the film deposited on the photoresist is also stripped, so as to complete the patterning of the film, so as to realize combining two times of photolithography into one through the process, to achieve reducing masks.

However, since the thin film is deposited on the photoresist (the material of the thin film may be metal, indium tin oxide, ITO and the like used to fabricate the TFT), thin film debris are carried into the stripper when the photoresist is lift-off, a large amount of thin film debris will cause clogging of the filter in the stripper machine, rendering the machine unusable.

Referring to FIG. 1, FIG. 1 is a schematic block diagram of the existing stripper machine, mainly including n level sequential arranged chambers 1, namely chamber_1˜chamber n, each level of chamber 1 has a corresponding tank 2, that is, tank_1 to tank n, and a filter 3, the arrows in the chamber 1, the tank 2, and the filter 3 indicate the direction of the flow of the stripper, and each chamber 1 is designed to fit the lift-off process for providing strippers to a glass substrate in the process, and the specific structure is not described herein again.

The glass substrate in the lift-off process is following the glass substrate passing direction, the stripper is supplied to the glass substrate from the chamber_1 to each level of the chamber_1 sequentially to perform the lift-off process. The stripper flows from the chamber_1 into the corresponding tank_1, then into the corresponding first filter 3, and entering into the second level of the chamber_2, and then through the second filter 3, and into the third level of the chamber_3 . . . .

In the existing stripper machine to perform the lift-off process, the filter 3 of the first and second level of chambers 1 is easily clogged seriously, due to the large amount of large-area thin film debris 4 in the stripper, and makes the machine unusable.

### SUMMARY

Therefore, an object of the present invention is to provide a stripper machine for a lift-off process, to solve the problem of filter clogging in the lift-off process.

Another object of the present invention is to provide a method for processing the stripper machine for the lift-off process, which solves the problem of filter clogging in a lift-off process.

To achieve the above object, the present invention provides a stripper machine for the lift-off process, including: a plurality of chambers arranged sequentially in multiple levels, a plurality of tanks correspondingly connected to the plurality of chambers, a plurality of filters correspondingly connected to the plurality of tanks, each the filters are connected to a next level chamber, a centrifugal filtration device is provided in each of the tank, wherein:

The plurality of chambers is used to provide a stripper to a glass substrate according to a level according to a transporting direction of the glass substrate in the lift-off process;

The tanks are for collecting and storing the stripper from the chamber undergoing the lift-off process;

The filters are for filtering the stripper from the tank, and deliver stripper to the next level chamber; and

The centrifugal filtration device is for separating and filtering out a thin film debris in the stripper in the tank from the stripper.

Wherein the centrifugal filtration device is set in an inner center of the tank.

Wherein the centrifugal filtration device is a rotary drum filter.

Wherein a circumferential wall of the rotary drum filter is provided with holes.

Wherein inner sides of a circumferential wall of the rotary drum filter is provided with a filter medium for filtering the thin film debris.

Wherein the filter medium is a filter mesh or a filter cloth.

Wherein the thin film debris is generated from a TFT fabricating process.

The present application further includes a method for processing a stripper machine in a lift-off process, including:

step 100: arranging multi-level chambers in sequence to provide a stripper to a glass substrate according to a level according to a transporting direction of the glass substrate in the lift-off process;

step 200: collecting and storing the stripper from a current level chamber undergoing the lift-off process into a tank corresponding to the current level chamber;

step 300: separating and filtering out a thin film debris and the stripper in the stripper in the tank of the current level chamber from the stripper by using a corresponding centrifugal filtration device; and

step 400, filtering the stripper from the tank of the current level chamber by using a corresponding filter of the current level chamber, and delivering the stripper to a next level chamber.

Wherein the centrifugal filtration device is a rotary drum filter.

Wherein inner sides of a circumferential wall of the rotary drum filter is provided with a filter medium for filtering the thin film debris.

The present application further includes a stripper machine for a lift-off process including: a plurality of chambers arranged sequentially in multiple levels, a plurality of tanks correspondingly connected to the plurality of chambers, a plurality of filters correspondingly connected to the plurality of tanks, each the filters are connected to a next level chamber, a centrifugal filtration device is provided in each of the tank, wherein:

The plurality of chambers is used to provide a stripper to a glass substrate according to a level according to a transporting direction of the glass substrate in the lift-off process;

The tanks are for collecting and storing the stripper from the chamber undergoing the lift-off process;

The filters are for filtering the stripper from the tank, and deliver stripper to the next level chamber;

The centrifugal filtration device is for separating and filtering out a thin film debris in the stripper in the tank from the stripper;

Wherein the centrifugal filtration device is set in an inner center of the tank.

Wherein the centrifugal filtration device is a rotary drum filter;

Wherein a circumferential wall of the rotary drum filter is provided with holes; and

Wherein inner sides of a circumferential wall of the rotary drum filter is provided with a filter medium for filtering the thin film debris.

In summary, the stripper machine for a lift-off process and a method for process thereof of the present invention is designed to improve the stripper machine for the lift-off process and the method for process thereof to solve the filter clogging problem of the traditional stripper machine in the lift-off process.

### BRIEF DESCRIPTION OF THE DRAWINGS

The technical solutions of the present invention and other beneficial effects will be apparent from the following detailed description of specific embodiments of the present invention with reference to the accompanying drawings.

In the drawings,

FIG. 1 is a schematic block diagram of the existing stripper machine; and

FIG. 2 is a schematic block diagram of a stripper machine for lift-off process in a preferred embodiment of the present invention; and

FIG. 3 is a flow chart of a method for processing the stripper machine for the lift-off process in a preferred embodiment of the present invention.

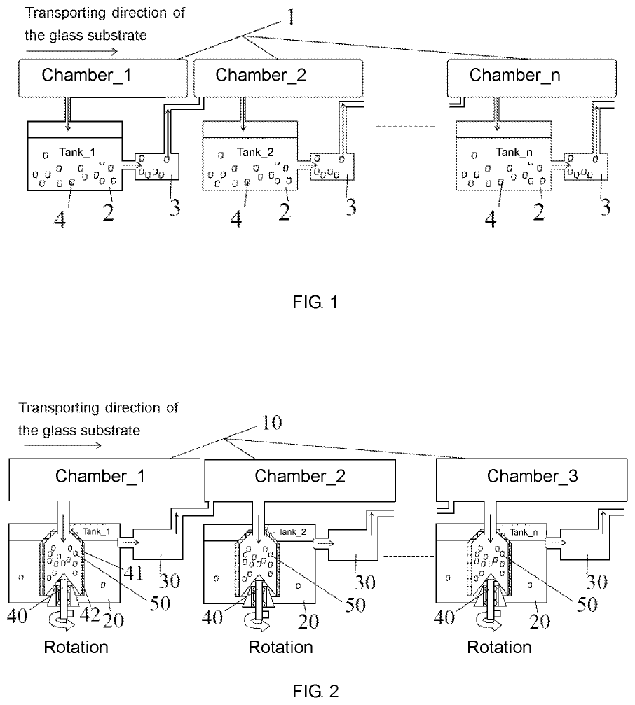

### DETAILED DESCRIPTION OF PREFERRED EMBODIMENTS

Referring to FIG. 2, FIG. 2 is a schematic block diagram of a stripper machine for lift-off process in a preferred embodiment of the present invention. The stripper machine used in the lift-off process of the present invention mainly includes: a plurality of chambers 10 arranged sequentially in multiple levels, that is, chamber_1 to chamber_n, arranged sequentially according to the level, the chamber 10 is configured to respectively provide stripper to the glass substrate according to the level according to the transporting direction of the glass substrate in the lift-off process; a plurality of tanks correspondingly connected to the plurality of chambers, each level of the chamber 10 is respectively connected with the corresponding tank 20 via a pipeline, that is tank_1 to tank_n, the tank 20 is for collecting and storing the stripper undergoing the lift-off process from the current level of chamber 10; a plurality of filters correspondingly connected to the plurality of tanks, the tanks 20 of each level of the chambers 10 may be respectively connected to respective filters 30 by pipelines, the filters 30 is used for filtering the stripper from the tank 20 of the current level chamber 10, and the filters 30 may also be connected to the next level of chamber 10 by pipelines, so that the filter 30 can deliver the filtered stripper to the next level chamber 10; the tank 20 of each chamber 10 is provided with a respective centrifugal filtration device 40, the centrifugal filtration device 40 is used for separating and filtering the thin film debris 50 in the stripper in the tank 20 from the stripper. The thin film debris 50 can be generated from metal, indium tin oxide, ITO or the like film layers used for the TFT fabrication, that is, the thin film debris 50 is generated in a TFT process.

Each chamber 10 is designed to be suitable for a lift-off process for providing a stripper to a glass substrate during the manufacturing process. For a specific structure, reference may be made to the existing design and will not be repeated here. Each level of chambers 10 is respectively connected to the corresponding tanks 20 by pipelines. The stripper after the lift-off process in the chamber 10 can be transported to the tank 20 by pipelines, and collected and stored by the tank 20. The tanks 20 of each level of chambers 10 is respectively connected to the corresponding filters 30 by pipelines, and the stripper processed by the tank 20 is further filtered by the corresponding filters 30, and then transported to the next level chamber 10 through the pipelines. In the present invention, the chamber 10 and the filter 30 can adopt the same design as in the conventional technology. Compared with the conventional technology, the present invention provides the centrifugal filter 40 in the tank 20 of each level chamber 10 respectively, the centrifugal force generated by the centrifugal filtration device 40 to the stripper in the tank 20 is used to filter the stripper, so as to solve the clogging problem of the filter of the conventional stripper machine in the lift-off process.

The glass substrate in the lift-off process is subjected to a lift-off process by providing a stripper from each chamber 1 to each level of the chamber 1o sequentially to the glass substrate in the glass substrate transporting direction. The stripper flows from the chamber_1 into the corresponding tank_1, filtered by the corresponding centrifugal filtration device 40 in the tank_1, and then filtered by the corresponding first filter 30 to enter the second level chamber_2, and filtered by the corresponding centrifugal filtration device 40 in the tank_2, and then filtered by the second filter 30, and then into the third level chamber_3 . . . .

The installation position of the centrifugal filtration device 40 may be selectively set in the center of the inside of the tank 20, and immersed in the stripper. Taking chamber_1 as an example, the stripper flowing out from the chamber_1 contains a large area of thin film debris 50, and enters into the centrifugal filtration device 40 of tank_1. The centrifugal filter device 40 can be selected from a variety of existing centrifugal filter devices, and can also be designed as needed. In the preferred embodiment, the centrifugal filter device 40 is a rotary drum filter. In the preferred embodiment of using the rotary drum filter, the design of a peripheral wall of the centrifugal filter device 40, that is the rotary drum filter, is designed as a circumferential wall, holes is arranged in the circumferential wall 41, an inner side of the circumferential wall 41 is arranged with a filter medium 42 for filtering the thin film debris 50, when the centrifugal filter device 40 is rotating, the centrifugal force generated by the centrifugal force field acts on the filter medium (filter mesh or filter cloth) 42, causing the stripper to pass through the filter medium 42 to become a clean stripper filtrate; and the thin film debris 50 are trapped in the rotary drum, to form a filter cake, thereby realizing to separate the stripper from the thin film debris 50. Therefore, the stripper flowing out of the tank 1 no longer contains the thin film chips 50, and thus clogging of the filter 30 in the machine is avoided. Each tank 20 is equipped with the centrifugal filtration device 40, by regularly cleaning the thin film debris 50 in the rotary drum to ensure the cleanliness of the stripper in each chamber 10 and no clogging of the filter 30.

The invention adopts the centrifugal filtering device to separate and filter the thin film debris and the stripper in the stripper, so as to keep the stripper not containing the thin film debris and keep it clean, so as to reenter into the chamber for recycling, and to solve the filter clogging problem of the stripper machine in the lift-off process.

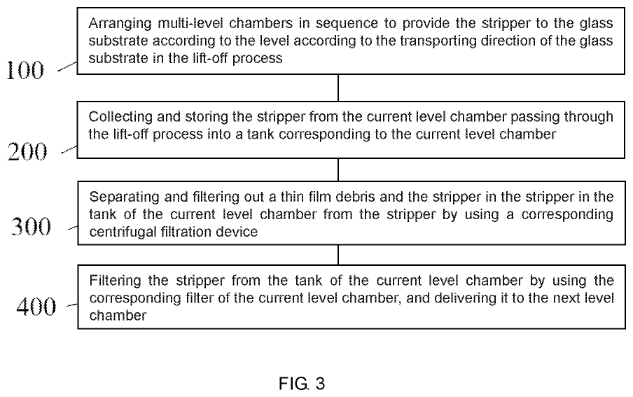

Referring to FIG. 3, the present invention also correspondingly provides a method for processing the stripper machine in the lift-off process, and may be applied to the stripper machine for lift-off process of the present invention, and mainly includes:

Step 100: arranging the multi-level chambers in sequence to provide the stripper to the glass substrate according to the level according to the transporting direction of the glass substrate in the lift-off process;

Step 200: Collecting and storing the stripper from the current level chamber undergoing the lift-off process into a tank corresponding to the current level chamber;

Step 300, separating and filtering out a thin film debris and the stripper in the stripper in the tank of the current level chamber from the stripper by using a corresponding centrifugal filtration device;

Step 400, filtering the stripper from the tank of the current level chamber by using the corresponding filter of the current level chamber, and delivering it to the next level chamber.

In summary, the stripper machine for the lift-off process and the method for processing thereof in the present invention are designed to improve the stripping machine used in the lift-off process and the method for processing thereof, to solve the clogging problem of the filter in the traditional stripper machine in the lift-off process.

The foregoing contents are detailed description of the disclosure in conjunction with specific preferred embodiments and concrete embodiments of the disclosure are not limited to these descriptions. For the person skilled in the art of the disclosure, without departing from the concept of the disclosure, simple deductions or substitutions can be made and should be included in the protection scope of the application.

What is claimed is:

1. A stripper machine for a lift-off process comprising: a plurality of chambers arranged sequentially in multiple levels, a plurality of tanks correspondingly connected to the plurality of chambers, a plurality of filters correspondingly connected to the plurality of tanks, each the filters are connected to a next level chamber, a centrifugal filtration device is provided in each of the tank, wherein:
the plurality of chambers is used to provide a stripper to a glass substrate according to a level according to a transporting direction of the glass substrate in the lift-off process;
the tanks are for collecting and storing the stripper from the chamber undergoing the lift-off process;
the filters are for filtering the stripper from the tank, and deliver stripper to the next level chamber; and
the centrifugal filtration device is for separating and filtering out a thin film debris in the stripper in the tank from the stripper.

2. The stripper machine for the lift-off process according to claim 1, wherein the centrifugal filtration device is set in an inner center of the tank.

3. The stripper machine for the lift-off process according to claim 1, wherein the centrifugal filtration device is a rotary drum filter.

4. The stripper machine for the lift-off process according to claim 3, wherein a circumferential wall of the rotary drum filter is provided with holes.

5. The stripper machine for the lift-off process according to claim 3, wherein inner sides of a circumferential wall of the rotary drum filter is provided with a filter medium for filtering the thin film debris.

6. The stripper machine for the lift-off process according to claim 5, wherein the filter medium is a filter mesh or a filter cloth.

7. The stripper machine for the lift-off process according to claim 1, wherein the thin film debris is generated from a TFT fabricating process.

8. A method for processing a stripper machine in a lift-off process, comprising:
step 100: arranging multi-level chambers in sequence to provide a stripper to a glass substrate according to a level according to a transporting direction of the glass substrate in the lift-off process;
step 200: collecting and storing the stripper from a current level chamber undergoing the lift-off process into a tank corresponding to the current level chamber;
step 300: separating and filtering out a thin film debris and the stripper in the stripper in the tank of the current level chamber from the stripper by using a corresponding centrifugal filtration device; and
step 400, filtering the stripper from the tank of the current level chamber by using a corresponding filter of the current level chamber, and delivering the stripper to a next level chamber.

9. The method for processing the stripper machine in the lift-off process according to claim 8, wherein the centrifugal filtration device is a rotary drum filter.

10. The method for processing the stripper machine in the lift-off process according to claim 9, wherein inner sides of a circumferential wall of the rotary drum filter is provided with a filter medium for filtering the thin film debris.

11. A stripper machine for a lift-off process comprising: a plurality of chambers arranged sequentially in multiple levels, a plurality of tanks correspondingly connected to the plurality of chambers, a plurality of filters correspondingly connected to the plurality of tanks, each the filters are connected to a next level chamber, a centrifugal filtration device is provided in each of the tank, wherein:
the plurality of chambers is used to provide a stripper to a glass substrate according to a level according to a transporting direction of the glass substrate in the lift-off process;
the tanks are for collecting and storing the stripper from the chamber undergoing the lift-off process;
the filters are for filtering the stripper from the tank, and deliver stripper to the next level chamber;
the centrifugal filtration device is for separating and filtering out a thin film debris in the stripper in the tank from the stripper;
wherein the centrifugal filtration device is set in an inner center of the tank.
wherein the centrifugal filtration device is a rotary drum filter;
wherein a circumferential wall of the rotary drum filter is provided with holes; and
wherein inner sides of a circumferential wall of the rotary drum filter is provided with a filter medium for filtering the thin film debris.

12. The stripper machine for the lift-off process according to claim 11, wherein the filter medium is a filter mesh or a filter cloth.

13. The stripper machine for the lift-off process according to claim 11, wherein the thin film debris is generated from a TFT fabricating process.
